(19) United States
(12) Patent Application Publication
(10) Pub. No.: US 2023/0086356 A1
(43) Pub. Date: Mar. 23, 2023

(54) GLASS CORE SUBSTRATE INCLUDING BUILDUPS WITH DIFFERENT NUMBERS OF LAYERS

(71) Applicant: Intel Corporation, Santa Clara, CA (US)

(72) Inventors: Andrew COLLINS, Chandler, AZ (US); Srinivas V. PIETAMBARAM, Chandler, AZ (US); Tarek A. IBRAHIM, Mesa, AZ (US); Sanka GANESAN, Chandler, AZ (US); Ram S. VISWANATH, Phoenix, AZ (US)

(21) Appl. No.: 17/481,237

(22) Filed: Sep. 21, 2021

(51) Int. Cl. H01L 23/498; H01L 21/48

(52) U.S. Cl. CPC H01L 23/49838; H01L 23/49827; H01L 21/486

(57) ABSTRACT

Embodiments described herein may be related to apparatuses, processes, and techniques directed to glass core-based substrates with an asymmetric number of front and back-side copper layers. In embodiments, the front and/or backside copper layers may be referred to as stack ups or as buildup layers on the glass core substrate. Embodiments may allow lower overall substrate layer counts by allowing for more front side layers where the signal routing may typically be highest, without requiring a matching, or symmetric, number of backside copper layers. Other embodiments may be described and/or claimed.

### FIELD

Embodiments of the present disclosure generally relate to the field of semiconductor packaging, and in particular to substrates with asymmetric buildup layers.

### BACKGROUND

Continued growth in computing and mobile devices will continue to increase the demand for increased signal quality and decreased size of semiconductor packages.

### BRIEF DESCRIPTION OF THE DRAWINGS

FIG. 1 illustrates a legacy symmetric substrate build up with high-speed serial input output (I/O) routing on a front side and direct pass-through on a backside.

FIG. 2 illustrates an asymmetric substrate build up with a high-speed serial I/O routing on the front side and streamlined vertical path on a backside, in accordance with various embodiments.

FIG. 3A-3H illustrate various stages in a manufacturing process for an asymmetric build up on a substrate, in accordance with various embodiments.

FIG. 4A-4H illustrate various stages in another manufacturing process for an asymmetric build up on a substrate, in accordance with various embodiments.

FIG. 5 illustrates multiple examples of laser-assisted etching of glass core processes, in accordance with embodiments.

FIG. 6 illustrates an example process for creating a substrate with an asymmetric buildup, in accordance with various embodiments.

FIG. 7 schematically illustrates a computing device, in accordance with various embodiments.

### DETAILED DESCRIPTION

Embodiments described herein may be related to apparatuses, processes, and techniques related to glass core-based substrates with an asymmetric number of front and back-side copper layers. In embodiments, the front and/or backside copper layers may be referred to as stack ups or as buildup layers on the glass core substrate. Embodiments may allow lower overall substrate layer counts by allowing for more front side layers where the signal routing may typically be highest, without requiring a matching, or symmetric, number of backside copper layers.

In embodiments, the techniques described herein may be used to reduce overall package layer count in order to reduce substrate factory fabrication throughput time, which can results in a lower price per unit and the option to fabricate more units in a fixed amount of time. In embodiments, these techniques may be used to ensure that all metal layers are fully utilized for each design. In particular, legacy substrates typically have a symmetric number for front/back side metal layers where >90% of the I/O routing takes place on the front side layers. Power delivery is also more critical on the front side layers. Thus, with legacy substrates, backside layer utilization from an electrical design perspective is low.”

In legacy implementations, substrates are fabricated with symmetric front and backside copper layer patterns. Typically, the corresponding front and back side layers are processed, either through etching or a plating process, at the same time. In many legacy substrates, a pitch translation through IO signal fanout routing from the bump scale to the plated through hole (PTH) scale pitches makes up most of the on-substrate routing. Thus, in these legacy implementations, medium and small die complexes frequently have back side layers that are underutilized.

Embodiments described herein may also include techniques and/or processes for patterning two glass core substrates at the same time, resulting in two or more finished substrates with an asymmetric number of front and backside copper layers. These techniques and/or processes may also be applied to standard substrates, for example, that may have higher routing requirements for front side layers. Embodiments may also be used for replacing passive silicon-based interposers, for example to be used with 3-D die stacking or direct chip attach architectures.

In addition, these techniques and/or processes may enable an efficient asymmetric front and backside copper layer patterning for glass substrates, and may reduce the total package layer count where metal signal routing requirements are not evenly distributed between the front and the back side layer metal features. Also, these techniques and/or processes may also improve throughput time and factory loading during manufacturing. In addition, eliminating underutilized metal layers, in comparison to legacy implementations, may improve substrate electrical performance by removing impedance discontinuities and parasitic capacitance that may degrade high-speed signaling performance.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

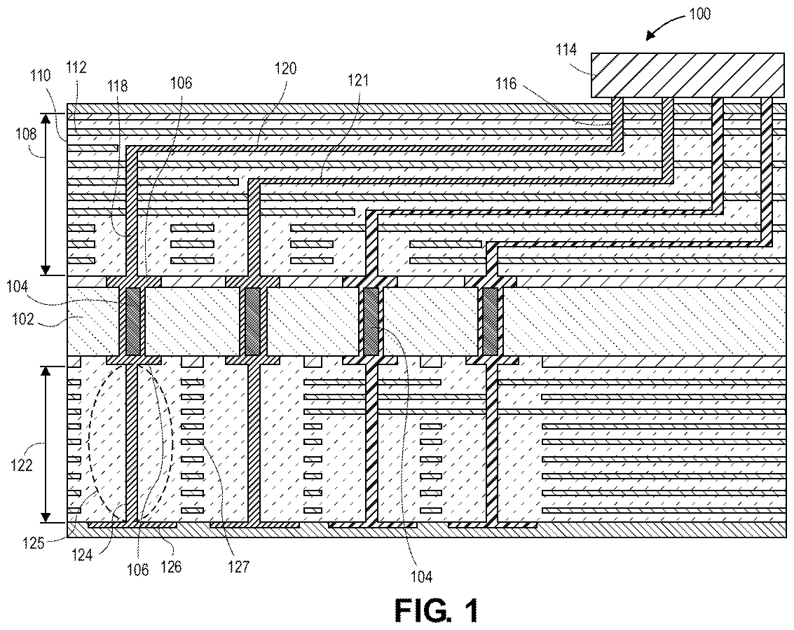

FIG. 1 illustrates a legacy symmetric substrate build up with high-speed serial I/O routing on a front side and direct pass-through on a backside. Legacy substrate 100 includes a core 102 that includes one or more plated through holes (PTH) 104 through the core 102. Copper or other electrically conductive pads 106 may be placed on either side of the core 102 and electrically coupled with the PTHs 104.

A first buildup 108 on the top side of the core 102 includes a plurality of layers that include dielectric layers 110 interleaved with copper layers 112. In implementations, the copper layers may be any other conductive metal or alloy. A die 114 may be electrically coupled with one of the PTH 104 within the first buildup 108, by being electrically coupled with one or more vias 116, 118 and electrical trace 120. Note that as implemented, the vias 116, 118 may extend through various layers of the first buildup 108. A second buildup 122 on the bottom side of the core 102 may include a via 124 that couples with a ball grid array (BGA) pad 126 at the bottom of the second buildup 122.

Legacy substrate 100 may be typical of a legacy substrate, where 70 to 95% of the signal routing may occur within the copper layers 112, 120, 121 of the first buildup 108, which may also be referred to as front side copper layers. The symmetric construction of the legacy substrate 100 does not effectively use the copper layers 127 in the second buildup 122, which may be referred to as backside copper layers. In some cases, the copper layers 127 in the second buildup 122 are an impediment to ideal electrical performance. For example, if the die 114 is a high-speed serial I/O die, for example a SERDES die, all of the die 114 to BGA pad 126 location routing is done on the first side of the substrate 100 in the first buildup 108 using one layer of routing 120, and just passes directly through the backside copper layers using via 124. This single routing layer 120 may be chosen due to the sensitivity of the signals, and a separation from other routing layers 121 that may be used by the die 114.

In legacy implementations used, for example, within programmable network switch product designs, there may be a high layer count within the first to build up 108 in the second buildup 122, such as 18 to 24 layers. In these examples, the vertical via 124 path through the second buildup 122 will add capacitance to the BGA pad 126 during operation, and may result in impedance discontinuities. Voiding 125 the metal on the second buildup 122 above BGA pads 126 signal pad may be implemented to reduce the impact of the ball grid array (BGA) pad capacitive coupling to the second buildup 122 ground layers above, but these large copper voids in the ground layers make consistent copper plating thickness during copper and patterning challenging due to changes in local copper density. For example (non-illustrated), changes in local copper density may occur with two regions in a substrate stack up using copper plating from a seed layer, where one region has a ˜40% metal density and the other has ˜90% metal density. After plating, the 40% region copper will plate much thicker than the 90% region. In this example, copper thickness tolerance control may be broken and may result in more resistive power planes in the 90% region and inaccurate signal impedance values in the 40% region. The result may be inconsistent copper and dielectric thicknesses, potentially resulting in yield loss.

In legacy implementations, substrate 100 may be an organic substrate with a copper clad laminate (CCL) core that may be laminated and/or pressed together. The material of the CCL core may include a polymer-based material with fibers, such as glass fibers or other fibers that have been added to the core to improve stiffness. However, when exposed to differences in temperature during operation or due to proximity to other heat sources, these fibers may expand and contract in different ways, and cause warping within the CCL core. In comparison, a glass core, as a single homogeneous material as discussed in embodiments further below, will not experience this type of warpage. In addition, a glass core may have a thickness up to 2½ times that of an organic core, which enables many fine features, such as through glass vias (TGV) that may be constructed with high aspect ratios and very narrow pitches.

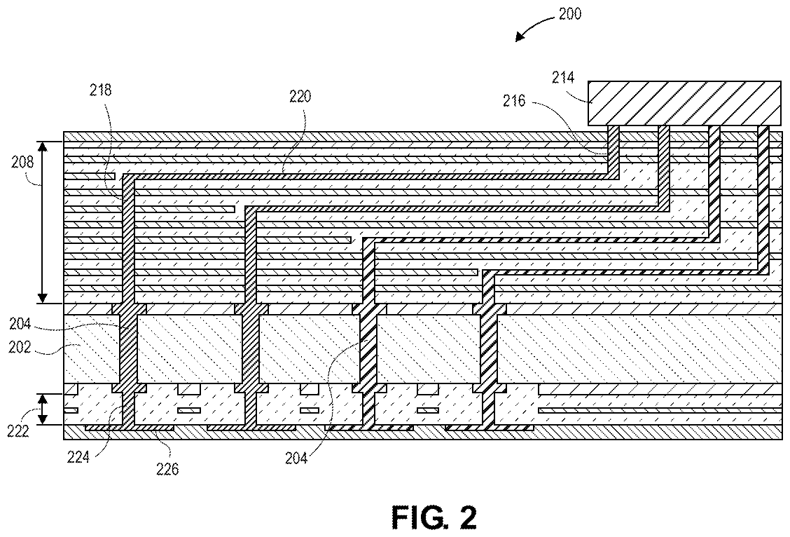

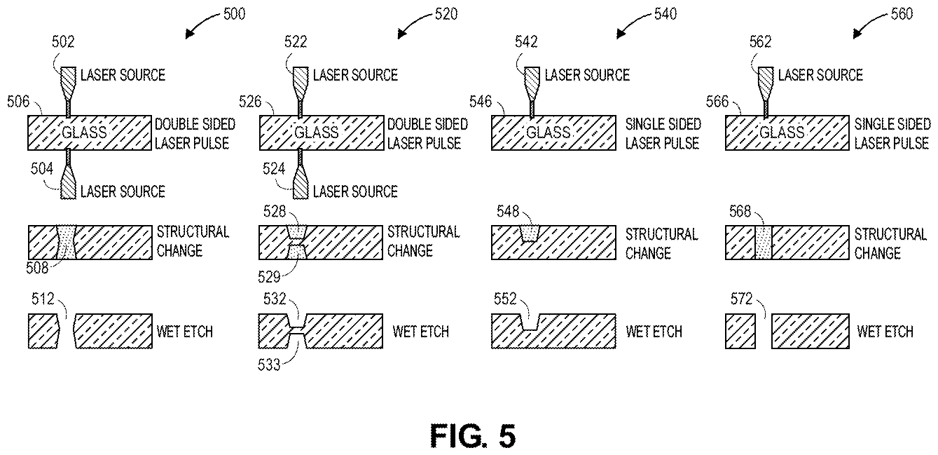

FIG. 2 illustrates an asymmetric substrate build up with a high-speed serial I/O routing on the front side and streamlined vertical path on a backside, in accordance with various embodiments. Substrate 200, which may be similar to substrate 100 of FIG. 1, includes a glass core 202, which may be similar to core 102 of FIG. 1, with a first buildup 208 and a second buildup 222. In embodiments, the first buildup 208 may be similar to the first buildup 108 of FIG. 1. In embodiments, the PTH 204, which may be similar to PTH 104, may be implemented using a TGV for a glass core and then subsequently filled with conductive material such as copper. Techniques for implementing TGV within a glass core are described in greater detail with respect to FIG. 5 below.

Substrate 200 may also have the a die 214, which may be similar to die 114 of FIG. 1, coupled with the first buildup 208 using vias 216, 218 and routing layer 220, which may be similar to vias 116, 118 and routing layer 120 of FIG. 1. Unlike substrate 100 of FIG. 1, substrate 200 is an example of an asymmetric substrate stack up, with a second buildup 222 that has fewer layers than the first buildup 208. This asymmetric architecture may be used to reduce the overall layer count of the substrate 200 as compared to substrate 100 of FIG. 1, as well as eliminate most of the impedance discontinuities and copper plating challenges for the short backside pass-through 224 of the die 214 connection with the BGA pad 226. In embodiments, a thickness of the glass core 202 may be adjusted and used as an insulator to prevent BGA pad 226 to metal capacitive coupling to the first buildup 208.

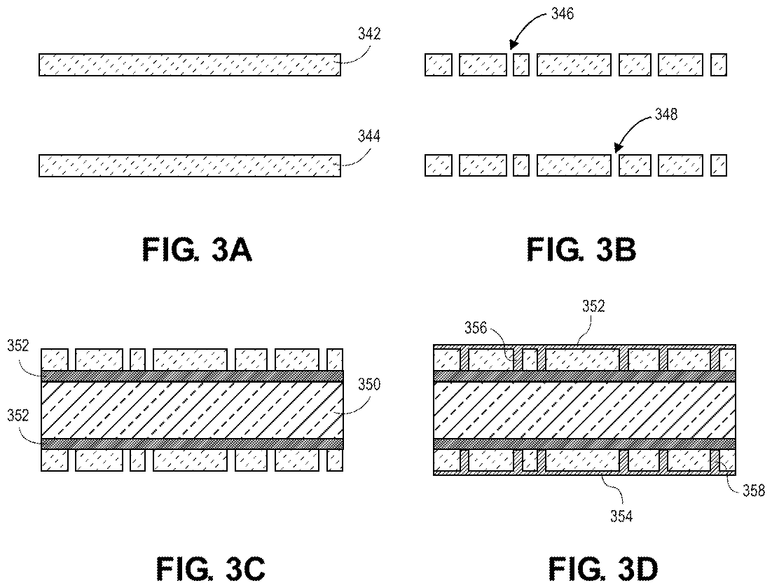

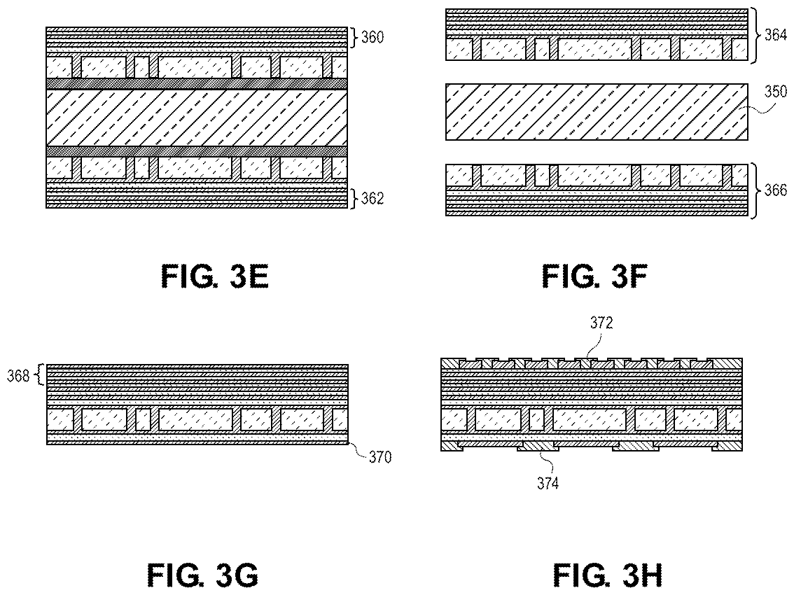

FIG. 3A-3H illustrate various stages in a manufacturing process for an asymmetric build up on a substrate, in accordance with various embodiments. FIG. 3A illustrates a stage in the manufacturing process where a first glass core 342 and a second glass core 344 are identified to create two separate substrates, such as substrate 200 of FIG. 2. In embodiments, the glass cores 342, 344 may include Borosilicate, Alumino Borosilicate, Soda Lime, Fused Silica or specialty glasses exhibiting low CTE (preferably <4) and low Dielectric Constant, Dk (<5.6) and low loss tangent (<0.01 @ 5 GHz). In embodiments, the first glass core 342 and the second glass core 344 may have the same thickness, or may be of different thicknesses.

FIG. 3B illustrates a stage in the manufacturing process where the glass cores 342, 344 are patterned with various TGVs 346, 348. In embodiments, these TGVs may be manufacturing using the techniques described with respect to FIG. 5 below. In embodiments, the pattern of the TGVs 346, 348 may be the same or may be different. In embodiments, other features, such as blind vias (not shown) may be created in the glass cores 342, 344 into which conductive elements and/or dielectric material may be inserted to create capacitors and/or conductor structures within the glass cores 342, 344.

FIG. 3C illustrates a stage in the manufacturing process where a removable carrier 350 is physically coupled with a side of the first glass core 342 and a side of the second glass core 344. In embodiments, an adhesive or epoxy or conductive copper tape 352 may be applied between the removable carrier 350 and the first glass core 342 and the second glass core 344. In embodiments, the adhesive or epoxy or conductive copper tape 352 may be removed as described further below.

FIG. 3D illustrates a stage in the manufacturing process where metal plating occurs that is used to produce outer metal layers 352, 354 and plated, or metal filled, TGVs 356, 358. In embodiments, this metal plating is done using a two-step process. First, a seed layer is formed by sputtering or e-less plating followed electrolytic plating process to fill the TGVs. TGV filling can may be accomplished using a reverse pulse, two-sided plating process commonly done in the substrate through hole filling process. In embodiments, the metal may be copper, or some other conductive element or alloy.

FIG. 3E illustrates a stage in the manufacturing process where additional metal layers 360, 362 are patterned. Note that additional metal layers 360, 362 may also include dielectric layers that separate each metal layer. Various routing and/or trace geometries may be placed as a part of the additional metal layers 360, 362. In embodiments, the additional metal layers 360, 362 may be similar to the first buildup 208 of FIG. 2.

FIG. 3F illustrates a stage in the manufacturing process where the removable carrier 350 is detached, leaving a first partially completed substrate 364 and a second partially completed substrate 366. In future stages of the manufacturing process, the first partially completed substrate 364 and the second partially completed substrate 366 may be subsequently processed individually.

FIG. 3G illustrates a stage the manufacturing process where the first partially completed substrate 364 may have additional metal layers 368, 370 additionally applied. In embodiments, the additional metal layers 368 may be additional layers to create a first buildup that may be similar to first buildup 208 of FIG. 2. In embodiments, the additional metal layers 370 may be additional layers to create a second buildup 222 of FIG. 2. Note that the metal layers 360, 362 as well as the additional metal layers 368, 370 may also include vertical electrical couplings that may be similar to vias 218, 220 of FIG. 2, or pass-through 224 of FIG. 2

FIG. 3H illustrates a stage in the manufacturing process where conductive pads 372, 374 may be added to provide electrical attachment points for other components, such as die 214 of FIG. 2. In embodiments, the pads 374 may be coupled with the motherboard or an interposer (not shown) via a BGA or socketed connection.

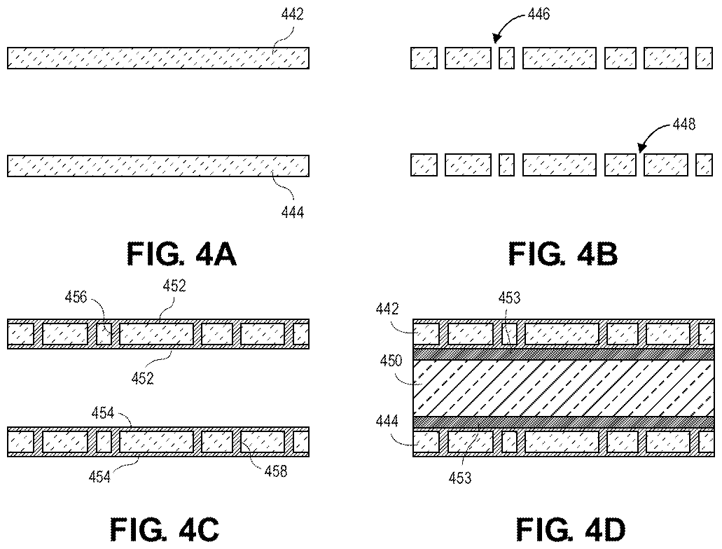

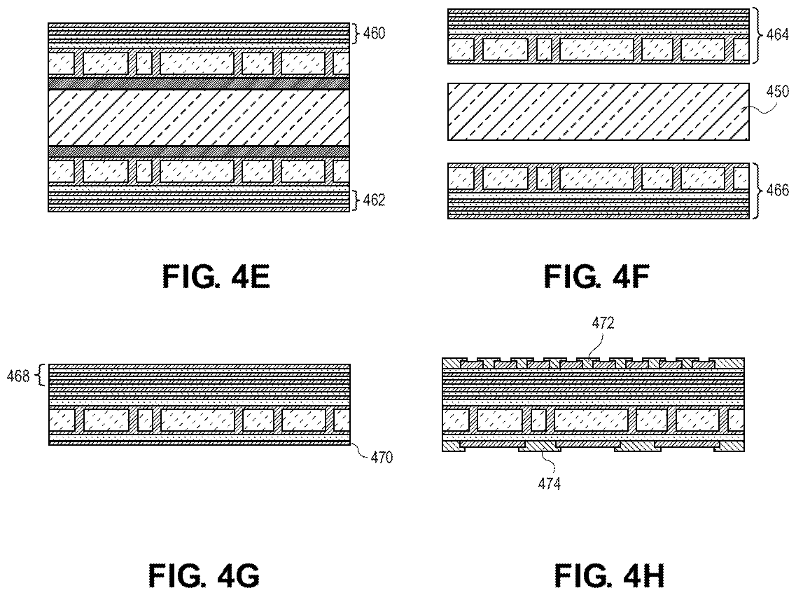

FIG. 4A-4H illustrate various stages in another manufacturing process for an asymmetric build up on a substrate, in accordance with various embodiments. FIG. 4A illustrates a stage in the manufacturing process where a first glass core 442 and a second glass core 444 are identified to be used to create two separate substrates, such as substrate 200 of FIG. 2. In embodiments, the glass cores 442, 444 may be similar to glass cores 342, 344 of FIG. 3A. In embodiments, the first glass core 442 and the second glass core 444 may have the same thickness, or may be of different thicknesses.

FIG. 4B illustrates a stage in the manufacturing process where the glass cores 442, 444 are patterned with various TGVs 446, 448. In embodiments, these TGVs may be manufacturing using the techniques described with respect to FIG. 5 below. In embodiments, other features, such as blind vias (not shown) may be created in the glass cores 442, 444 into which conductive elements and/or dielectric material may be inserted to create capacitors and/or conductor structures within the glass cores 442, 444.

FIG. 4C illustrates a stage in the manufacturing process where metal plating occurs that produces outer metal layers 452 on glass core 442 and outer metal layers 454 on glass core 444, as well as plated TGV 456 on the glass core 442 and plated TGV 458 on the glass core 444. In embodiments, the metal may be copper, or may be some other conductive element or alloy.

FIG. 4D illustrates a stage in the manufacturing process where a removable carrier 450 is physically coupled with the metal layer 452 on the side of the first glass core 442 and with the metal layer 454 on the side of the second glass core 444. In embodiments, an adhesive or epoxy 453 or conductive copper tape may be applied between the removable carrier 450 and the first glass core 442 and between the removable carrier 450 and the second glass core 444. In embodiments, the removable carrier 450 may be bound the adhesive or epoxy 453 or conductive copper tape any may be subsequently removed as described further below.

FIG. 4E illustrates a stage in the manufacturing process where additional metal layers 460, 462 are patterned. Note, additional metal layers 460, 462 may also include dielectric layers that separate each individual layer. In embodiments, the additional metal layers 460, 462 may be similar to the first buildup 208 of FIG. 2.

FIG. 4F illustrates a stage in the manufacturing process where the removable carrier 450 is detached, leaving a first partially completed substrate 464 and a second partially completed substrate 466. In future stages of the manufacturing process, the first partially completed substrate 464 and the second partially completed substrate 466 may be subsequently processed individually.

FIG. 4G illustrates a stage the manufacturing process where the first partially completed substrate 464 may have additional metal layers 468, 470 applied. In embodiments, the additional metal layers 468 may be additional layers to create a first buildup that may be similar to first buildup 208 of FIG. 2. In embodiments, the additional metal layers 470 may be additional layers to create a second buildup similar to second buildup 222 of FIG. 2. Note that the metal layers 460, 462 as well as the additional metal layers 468, 470 may also include vertical electrical couplings that may be similar to vias 218, 220 of FIG. 2, or pass-through 224 of FIG. 2.

FIG. 4H illustrates a stage in the manufacturing process where conductive pads 472, 474 may be added to provide electrical attachment points for other components, such as die 214 of FIG. 2. In embodiments, the pads 474 may be coupled with the motherboard or an interposer (not shown) via a BGA contact (not shown).

FIG. 5 illustrates multiple examples of laser-assisted etching of glass interconnects processes (which may be referred to as “LEGIT” herein), in accordance with embodiments. One use of the LEGIT technique is to provide an alternative substrate core material to the legacy copper clad laminate (CCL) core used in semiconductor packages used to implement products such as servers, graphics, clients, 5G, and the like. By using laser-assisted etching, crack free, high density via drills, hollow shapes may be formed into a glass substrate. In embodiments, different process parameters may be adjusted to achieve drills of various shapes and depths, thus opening the door for innovative devices, architectures, processes, and designs in glass. Embodiments, such as the bridge discussed herein, may also take advantage of these techniques.

Diagram 500 shows a high level process flow for a through via and blind via (or trench) in a microelectronic package substrate (e.g. glass) using LEGIT to create a through via or a blind via. A resulting volume/shape of glass with laser-induced morphology change that can then be selectively etched to create a trench, a through hole or a void that can be filled with conductive material. A through via 512 is created by laser pulses from two laser sources 502, 504 on opposite sides of a glass wafer 506. As used herein, a through drill and a through via refers to when the drill or the via starts on one side of the glass/substrate and ends on the other side. A blind drill and a blind via refers to when the drill or the via starts on the surface of the substrate and stops half way inside the substrate. In embodiments, the laser pulses from the two laser sources 502, 504 are applied perpendicularly to the glass wafer 506 to induce a morphological change 508, which may also be referred to as a structural change, in the glass that encounters the laser pulses. This morphological change 508 includes changes in the molecular structure of the glass to make it easier to etch out (remove a portion of the glass). In embodiments, a wet etch process may be used.

Diagram 520 shows a high level process flow for a double blind shape. A double blind shape 532, 533 may be created by laser pulses from two laser sources 522, 524, which may be similar to laser sources 502, 504, that are on opposite sides of the glass wafer 526, which may be similar to glass wafer 506. In this example, adjustments may be made in the laser pulse energy and/or the laser pulse exposure time from the two laser sources 522, 524. As a result, morphological changes 528, 529 in the glass 526 may result, with these changes making it easier to etch out portions of the glass. In embodiments, a wet etch process may be used.

Diagram 540 shows a high level process flow for a single-blind shape, which may also be referred to as a trench. In this example, a single laser source 542 delivers a laser pulse to the glass wafer 546 to create a morphological change 548 in the glass 546. As described above, these morphological changes make it easier to etch out a portion of the glass 552. In embodiments, a wet etch process may be used.

Diagram 560 shows a high level process flow for a through via shape. In this example, a single laser source 562 applies a laser pulse to the glass 566 to create a morphological change 568 in the glass 566, with the change making it easier to etch out a portion of the glass 572. As shown here, the laser pulse energy and/or laser pulse exposure time from the laser source 562 has been adjusted to create an etched out portion 572 that extends entirely through the glass 566.

With respect to FIG. 5, although embodiments show laser sources 502, 504, 522, 524, 542, 562 as perpendicular to a surface of the glass 506, 526, 546, 566, in embodiments, the laser sources may be positioned at an angle to the surface of the glass, with pulse energy and/or pulse exposure time variations in order to cause a diagonal via or a trench, or to shape the via, such as 512, 572, for example to make it cylindrical, tapered, or include some other feature. In addition, varying the glass type may also cause different features within a via or a trench as the etching of glass is strongly dependent on the chemical composition of the glass.

In embodiments using the process described with respect to FIG. 5, through hole vias 512, 572 may be created that are less than 10 μm in diameter, and may have an aspect ratio of 40:1 to 50:1. As a result, a far higher density of vias may be placed within the glass and be placed closer to each other at a fine pitch. In embodiments, this pitch may be 50 μm or less. After creating the vias or trenches, a metallization process may be applied in order to create a conductive pathway through the vias or trenches, for example a plated through hole (PTH). Using these techniques, finer pitch vias may result in better signaling, allowing more I/O signals to be routed through the glass wafer and to other coupled components such as a substrate.

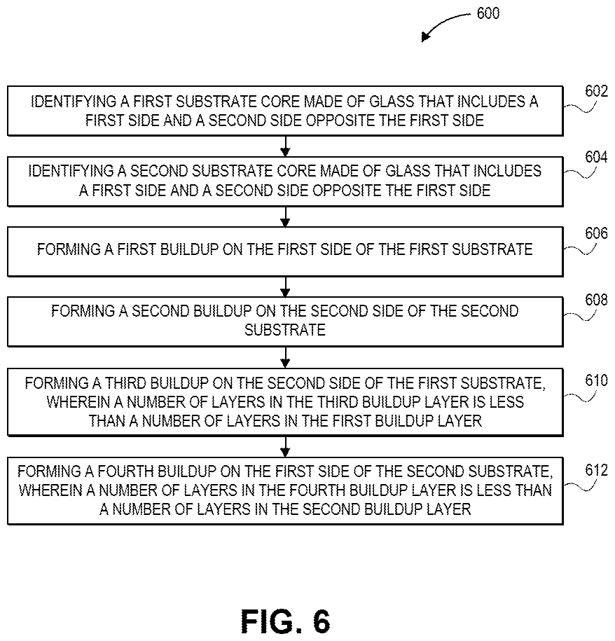

FIG. 6 illustrates an example process for creating a substrate with an asymmetric buildup, in accordance with various embodiments. Process 600 may be performed using the techniques, methods, systems, and/or apparatus as described with respect to FIGS. 1-5, or of any other embodiment described herein.

At block 602, the process may include identifying a first substrate core made of glass that includes a first side and a second side opposite the first side. In embodiments, the first substrate core may be similar to glass substrate core 202 of FIG. 2, glass core 342 of FIG. 3A, or glass core 442 of FIG. 4A.

At block 604, the process may further include identifying a second substrate core made of glass that includes a first side and a second side opposite the first side. In embodiments, the second substrate core may be similar to glass substrate core 202 of FIG. 2, glass core 344 of FIG. 3A, or glass core 444 of FIG. 4A.

At block 606, the process may further include forming a first buildup on the first side of the first substrate. In embodiments, the first buildup on the first side of the first substrate may be similar to outer metal layer 352 of FIG. 3D, or additional metal layers 360 of FIG. 3E.

At block 608, the process may further include forming a second buildup on the second side of the second substrate. In embodiments, the second buildup on the second side of the second substrate may be similar to outer metal layer 354 of FIG. 3D, or additional metal layers 362 of FIG. 3E.

At block 610, the process may further include forming a third buildup on the second side of the first substrate, wherein a number of layers in the third buildup layer is less than a number of layers in the first buildup layer. In embodiments, the third buildup on the second side of the first substrate may be similar to layer 370 of FIG. 3G.

At block 612, the process may further include forming a fourth buildup on the first side of the second substrate, wherein a number of layers in the fourth buildup layer is less than a number of layers in the second buildup layer. In embodiments, the fourth buildup on the first side of the second substrate may be similar to layer 370 of FIG. 3G.

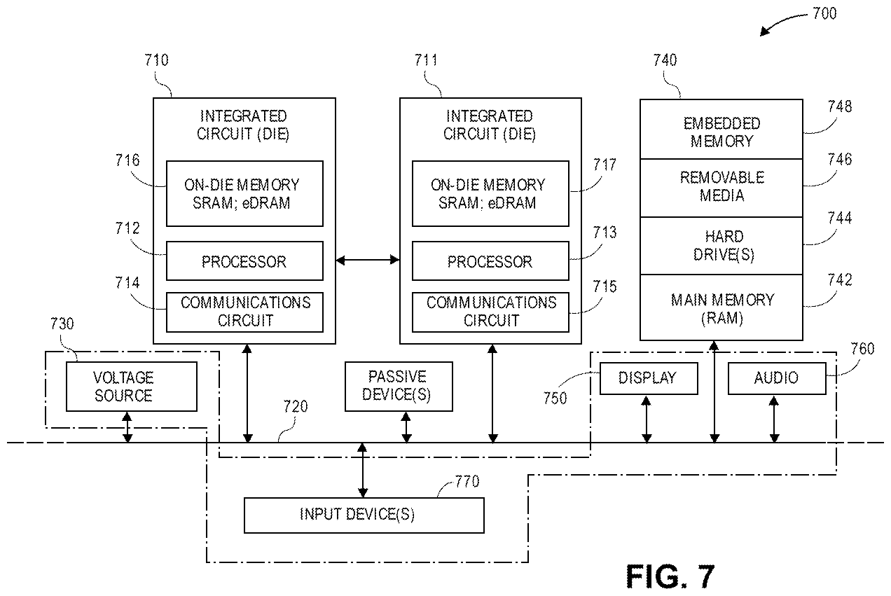

FIG. 7 schematically illustrates a computing device, in accordance with various embodiments. FIG. 7 is a schematic of a computer system 700, in accordance with an embodiment of the present invention. The computer system 700 (also referred to as the electronic system 700) as depicted can embody a glass core substrate including buildups with different numbers of layers, according to any of the several disclosed embodiments and their equivalents as set forth in this disclosure. The computer system 700 may be a mobile device such as a netbook computer. The computer system 700 may be a mobile device such as a wireless smart phone. The computer system 700 may be a desktop computer. The computer system 700 may be a hand-held reader. The computer system 700 may be a server system. The computer system 700 may be a supercomputer or high-performance computing system.

In an embodiment, the electronic system 700 is a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In some embodiments, the voltage source 730 supplies current to the integrated circuit 710 through the system bus 720.

The integrated circuit 710 is electrically coupled to the system bus 720 and includes any circuit, or combination of circuits according to an embodiment. In an embodiment, the integrated circuit 710 includes a processor 712 that can be of any type. As used herein, the processor 712 may mean any type of circuit such as, but not limited to, a microprocessor, a microcontroller, a graphics processor, a digital signal processor, or another processor. In an embodiment, the processor 712 includes, or is coupled with, a glass core substrate including buildups with different numbers of layers, as disclosed herein. In an embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM).

In an embodiment, the integrated circuit 710 is complemented with a subsequent integrated circuit 711. Useful embodiments include a dual processor 713 and a dual communications circuit 715 and dual on-die memory 717 such as SRAM. In an embodiment, the dual integrated circuit 710 includes embedded on-die memory 717 such as eDRAM.

In an embodiment, the electronic system 700 also includes an external memory 740 that in turn may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also be embedded memory 748 such as the first die in a die stack, according to an embodiment.

In an embodiment, the electronic system 700 also includes a display device 750, an audio output 760. In an embodiment, the electronic system 700 includes an input device such as a controller 770 that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

As shown herein, the integrated circuit 710 can be implemented in a number of different embodiments, including a package substrate having a glass core substrate including buildups with different numbers of layers, according to any of the several disclosed embodiments and their equivalents, an electronic system, a computer system, one or more methods of fabricating an integrated circuit, and one or more methods of fabricating an electronic assembly that includes a package substrate having a glass core substrate including buildups with different numbers of layers, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a glass core substrate including buildups with different numbers of layers embodiments and their equivalents. A foundation substrate may be included, as represented by the dashed line of FIG. 7. Passive devices may also be included, as is also depicted in FIG. 7.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 is a substrate comprising: a glass core with a first side and a second side opposite the first side; a first buildup coupled with the first side of the glass core, the first buildup including one or more layers; a second buildup coupled with the second side of the glass core, the second buildup including one or more layers; and wherein a number of the one or more layers of the first buildup is different than a number of the one or more layers of the second buildup.

Example 2 includes the substrate of example 1, wherein the one or more layers of the first buildup or the one or more layers of the second buildup include copper layers.

Example 3 includes the substrate of example 1, wherein the glass core further includes one or more through glass vias (TGV) that extend from the first side of the glass core to the second side the glass core.

Example 4 includes the substrate of example 3, wherein the one or more TGV are filled with an electrically conductive material.

Example 5 includes the substrate of example 4, wherein the one or more TGV have a pitch that is less than 150 μm.

Example 6 includes the substrate of example 4, wherein at least one of the one or more layers of the first buildup are electrically coupled with one of the one or more TGV; and wherein at least one of the one or more layers of the second buildup are electrically coupled with the one of the one or more TGV.

Example 7 includes the substrate of example 6, wherein the number of the one or more layers of the first buildup is greater than the number of the one or more layers of the second buildup; and further comprising a die coupled with the first buildup, the die electrically coupled with the one of the one or more layers of the first buildup.

Example 8 includes the substrate of any one of examples 1-7, wherein a first volume of copper within the first buildup is greater than or equal to one half of a second volume of a copper within the second buildup.

Example 9 is a method comprising: identifying a first substrate core made of glass that includes a first side and a second side opposite the first side; identifying a second substrate core made of glass that includes a first side and a second side opposite the first side; forming a first buildup on the first side of the first substrate; forming a second buildup on the second side of the second substrate; forming a third buildup on the second side of the first substrate, wherein a number of layers in the third buildup layer is less than a number of layers in the first buildup layer; and forming a fourth buildup on the first side of the second substrate, wherein a number of layers in the fourth buildup layer is less than a number of layers in the second buildup layer.

Example 10 includes the method of example 9, wherein identifying the first substrate core further includes patterning the first substrate core with one or more through glass vias (TGVs); and wherein identifying the second substrate core further includes patterning the second substrate core with one or more TGVs.

Example 11 includes the method of example 9, further comprising, after identifying the second substrate core: attaching the second side of the first substrate core to a first side of a core carrier; and attaching the first side of the second substrate core to a second side of a core carrier, the second side of the core carrier opposite the first side of the core carrier.

Example 12 includes the method of example 11, wherein the core carrier is a glass core carrier.

Example 13 includes the method of any one of examples 9-12, further comprising, after forming the second buildup: detaching the first substrate from the core carrier; and detaching the second substrate from the core carrier.

Example 14 includes the method of any one of examples 9-12, further comprising applying metal pads to a side of the first buildup, the second buildup, the third buildup, or the forth buildup.

Example 15 is a package comprising: an interposer that includes: a glass core with a first side and a second side opposite the first side; a first buildup coupled with the first side of the glass core, the first buildup including a plurality of layers that include at least one copper layer; a second buildup coupled with the second side of the glass core, the second buildup including a plurality of layers that include at least one copper layer; and wherein a number of the plurality of layers of the first buildup is greater than a number of the plurality of layers of the second buildup; a die coupled with the first buildup.

Example 16 includes the package of example 15, wherein the glass core further includes one or more through glass vias (TGV) that extend from the first side of the glass core to the second side the glass core, wherein the one or more TGV are filled with copper.

Example 17 includes the package of example 16, wherein at least one of the plurality of layers of the first buildup is electrically coupled with one of the one or more TGV filled with copper; and wherein at least one of the plurality of layers of the second buildup is electrically coupled with the one of the one or more TGV filled with copper.

Example 18 includes the package of any one of examples 15-17, wherein the interposer includes a first pad on the first buildup layer and a second pad on the second buildup layer, wherein the first pad and the second pad are electrically coupled through one of the one or more TGV filled with copper.

Example 19 includes the package of example 18, wherein the die is electrically coupled with the first pad.

Example 20 includes the package of any one of examples 15-19, wherein the second buildup is electrically or physically coupled with a substrate.

What is claimed is:

1. A substrate comprising:
a glass core with a first side and a second side opposite the first side;
a first buildup coupled with the first side of the glass core, the first buildup including one or more layers;
a second buildup coupled with the second side of the glass core, the second buildup including one or more layers; and
wherein a number of the one or more layers of the first buildup is different than a number of the one or more layers of the second buildup.

2. The substrate of claim 1, wherein the one or more layers of the first buildup or the one or more layers of the second buildup include copper layers.

3. The substrate of claim 1, wherein the glass core further includes one or more through glass vias (TGV) that extend from the first side of the glass core to the second side the glass core.

4. The substrate of claim 3, wherein the one or more TGV are filled with an electrically conductive material.

5. The substrate of claim 4, wherein the one or more TGV have a pitch that is less than 150 μm.

6. The substrate of claim 4, wherein at least one of the one or more layers of the first buildup are electrically coupled with one of the one or more TGV; and wherein at least one of the one or more layers of the second buildup are electrically coupled with the one of the one or more TGV.

7. The substrate of claim 6, wherein the number of the one or more layers of the first buildup is greater than the number of the one or more layers of the second buildup; and
further comprising a die coupled with the first buildup, the die electrically coupled with the one of the one or more layers of the first buildup.

8. The substrate of claim 1, wherein a first volume of copper within the first buildup is greater than or equal to one half of a second volume of a copper within the second buildup.

9. A method comprising:
identifying a first substrate core made of glass that includes a first side and a second side opposite the first side;
identifying a second substrate core made of glass that includes a first side and a second side opposite the first side;
forming a first buildup on the first side of the first substrate;
forming a second buildup on the second side of the second substrate;
forming a third buildup on the second side of the first substrate, wherein a number of layers in the third buildup layer is less than a number of layers in the first buildup layer; and
forming a fourth buildup on the first side of the second substrate, wherein a number of layers in the fourth buildup layer is less than a number of layers in the second buildup layer.

10. The method of claim 9, wherein identifying the first substrate core further includes patterning the first substrate core with one or more through glass vias (TGVs); and
wherein identifying the second substrate core further includes patterning the second substrate core with one or more TGVs.

11. The method of claim 9, further comprising, after identifying the second substrate core:
attaching the second side of the first substrate core to a first side of a core carrier; and
attaching the first side of the second substrate core to a second side of a core carrier, the second side of the core carrier opposite the first side of the core carrier.

12. The method of claim 11, wherein the core carrier is a glass core carrier.

13. The method of claim 9, further comprising, after forming the second buildup:
detaching the first substrate from the core carrier; and
detaching the second substrate from the core carrier.

14. The method of claim 9, further comprising applying metal pads to a side of the first buildup, the second buildup, the third buildup, or the forth buildup.

15. A package comprising:
an interposer that includes:
a glass core with a first side and a second side opposite the first side;
a first buildup coupled with the first side of the glass core, the first buildup including a plurality of layers that include at least one copper layer;
a second buildup coupled with the second side of the glass core, the second buildup including a plurality of layers that include at least one copper layer; and
wherein a number of the plurality of layers of the first buildup is greater than a number of the plurality of layers of the second buildup;
a die coupled with the first buildup.

16. The package of claim 15, wherein the glass core further includes one or more through glass vias (TGV) that extend from the first side of the glass core to the second side the glass core, wherein the one or more TGV are filled with copper.

17. The package of claim 16, wherein at least one of the plurality of layers of the first buildup is electrically coupled with one of the one or more TGV filled with copper; and wherein at least one of the plurality of layers of the second buildup is electrically coupled with the one of the one or more TGV filled with copper.

18. The package of claim 15, wherein the interposer includes a first pad on the first buildup layer and a second pad on the second buildup layer, wherein the first pad and the second pad are electrically coupled through one of the one or more TGV filled with copper.

19. The package of claim 18, wherein the die is electrically coupled with the first pad.

20. The package of claim 15, wherein the second buildup is electrically or physically coupled with a substrate.
